(19) United States
(12) Patent Application Publication
(10) Pub. No.: US 2010/0097846 A1
(43) Pub. Date: Apr. 22, 2010

(54) MAGNETORESISTIVE ELEMENT AND MAGNETIC MEMORY

(75) Inventors: Kuniaki Sugiura, Fujisawa-shi (JP); Takeshi Kajiyama, Yokohama-shi (JP); Yoshiaki Asao, Sagamihara-shi (JP); Shigeki Takahashi, Yokohama-shi (JP); Minoru Amano, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/563,465

(22) Filed: Sep. 21, 2009

(30) Foreign Application Priority Data
Oct. 22, 2008 (JP) 2008-271847

(51) Int. Cl. G11C 11/02; H01L 29/82

(52) U.S. Cl. 365/158; 257/421; 257/E29.323

(57) ABSTRACT

A magnetic memory includes an interlayer insulation layer provided on a substrate, a conductive underlying layer provided on the interlayer insulation layer, and a magnetoresistive element provided on the underlying layer and including two magnetic layers and a nonmagnetic layer interposed between the magnetic layers. The underlying layer has an etching rate lower than an etching rate of each of the magnetic layers.

### CROSS-REFERENCE TO RELATED APPLICATIONS

This application is based upon and claims the benefit of priority from prior Japanese Patent Application No. 2008-271847, filed Oct. 22, 2008, the entire contents of which are incorporated herein by reference.

### BACKGROUND OF THE INVENTION

1. Field of the Invention

The present invention relates to a magnetoresistive element and a magnetic memory, and more particularly, to a magnetoresistive element and a magnetic memory for storing data using the magnetoresistive effect.

2. Description of the Related Art

A magnetic random access memory (MRAM), which uses a magnetoresistive effect in reading data, holds significant promise for practical use as a universal memory including all the elements necessary for a memory, in terms of high-speed operation, non-volatility, and the number of times it can be rewritten.

Many MRAMs using an element exhibiting a magnetoresistive effect called the tunneling magnetoresistive (TMR) effect have been reported. In general, TMR effect elements have a stacked structure including two magnetic layers and a nonmagnetic layer (tunnel barrier layer) interposed therebetween, and use magnetic tunnel junction (MTJ) elements, which use a change in magnetoresistance resulting from the spin-polarized tunneling effect. MTJ elements can assume a low- and a high-resistance state according to magnetization alignment of the two magnetic layers. By defining the low-resistance state as binary 0 and the high-resistance state as binary 1, an MTJ element can record one binary digit.

An MRAM using a write system called spin momentum transfer (SMT, hereinafter referred to as spin injection) is known. In a spin-injection MRAM, a write current is directly influenced by the size of elements. That is, in order to achieve integration of a spin-injection MRAM, it is important to minimize the size of elements and achieve a high yield that does not produce defective cells in the manufacturing process.

When an MTJ element is processed by sputter-etching, the problem of redeposition, which is adhesion of a reaction product to a circumferential surface of the MTJ, occurs. Since the incident angle of an ion beam used for sputter-etching is large on the circumferential surface of the MTJ, redeposition, which basically competes with etching in sputter-etching, gains superiority over the etching rate. In general, the etching rate suddenly decreases when the incident angle is high (greater than or equal to 70°, for example) with respect to the normal of the etching surface. As a result, the etched MTJ is greater in size than it was at the time of formation of a hard mask, which makes it difficult to miniaturize the MTJ.

Moreover, when an MTJ including a tunnel barrier layer is etched, a deposit resulting from redeposition adheres to the circumferential surface of the tunnel barrier layer. This generates a short path between the magnetic layers, resulting in substantial increase in incidence of defect MTJ elements, and of defect MRAMs in turn. It is therefore important to develop a process of suppressing or eliminating redeposition in etching MTJs.

As a related technique of this kind, in processing an MTJ with a top pin structure, a process of performing etching to a fixed layer once, covering the fixed layer with an insulation layer, and then etching the recording layer, is disclosed (Japanese Patent KOKAI Publication No. 2004-349671).

### BRIEF SUMMARY OF THE INVENTION

According to an aspect of the present invention, there is provided a magnetic memory comprising: an interlayer insulation layer provided on a substrate; a conductive underlying layer provided on the interlayer insulation layer; and a magnetoresistive element provided on the underlying layer and including two magnetic layers and a nonmagnetic layer interposed between the magnetic layers, wherein the underlying layer has an etching rate lower than an etching rate of each of the magnetic layers.

According to an aspect of the present invention, there is provided a magnetic memory comprising: an interlayer insulation layer provided on a substrate; a contact provided in the interlayer insulation layer; an insulating stopper layer provided on the interlayer insulation layer to surround the contact; and a magnetoresistive element provided on the contact and including two magnetic layers and a non-magnetic layer interposed between the magnetic layers, wherein the stopper layer has an etching rate lower than an etching rate of each of the magnetic layers.

According to an aspect of the present invention, there is provided a magnetoresistive element comprising: a stacked structure provided on an underlying layer and including a first magnetic layer, a non-magnetic layer, and a second magnetic layer are sequentially stacked; and a sidewall provided on the nonmagnetic layer to cover a circumferential surface of the second magnetic layer, made of an insulating material, and having an etching rate lower than an etching rate of the first magnetic layer.

### BRIEF DESCRIPTION OF THE SEVERAL VIEWS OF THE DRAWING

FIG. 1 is a cross-sectional view illustrating a configuration of an MTJ element 10 according to the first embodiment of the present invention;

FIG. 2 illustrates overetching performed to remove a deposit on the circumferential surface of the MTJ;

FIG. 3 is a graph illustrating the relationship between the etching rate and the incident angle of the ion beam;

FIG. 4 is a cross-sectional view illustrating a configuration of an MRAM according to the first embodiment;

FIG. 5 is a cross-sectional view illustrating a manufacturing step of the MRAM according to the first embodiment;

FIG. 6 is a cross-sectional view illustrating a manufacturing step of the MRAM subsequent to FIG. 5;

FIG. 7 is a cross-sectional view illustrating a manufacturing step of the MRAM subsequent to FIG. 6;

FIG. 8 is a cross-sectional view illustrating a manufacturing step of the MRAM subsequent to FIG. 7;

FIG. 9 is a cross-sectional view illustrating a manufacturing step of the MRAM subsequent to FIG. 8;

FIG. 10 is a cross-sectional view illustrating a manufacturing step of the MRAM subsequent to FIG. 9;

FIG. 11 is a cross-sectional view illustrating a manufacturing step of the MRAM subsequent to FIG. 10;

FIG. 12 is a cross-sectional view illustrating a configuration of an MRAM according to the second embodiment of the present invention;

FIG. 13 is a cross-sectional view illustrating another configuration example of the MRAM according to the second embodiment;

FIG. 14 is a cross-sectional view illustrating a manufacturing step of the MRAM according to the second embodiment;

FIG. 15 is a cross-sectional view illustrating a manufacturing step of the MRAM subsequent to FIG. 14;

FIG. 16 is a cross-sectional view illustrating a manufacturing step of the MRAM subsequent to FIG. 15;

FIG. 17 is a cross-sectional view illustrating a manufacturing step of the MRAM subsequent to FIG. 16;

FIG. 18 is a cross-sectional view illustrating a manufacturing step of the MRAM subsequent to FIG. 17;

FIG. 19 is a cross-sectional view illustrating a manufacturing step of another configuration example of the MRAM;

FIG. 20 is a cross-sectional view illustrating a manufacturing step of the MRAM subsequent to FIG. 19;

FIG. 21 is a plan view illustrating a configuration of an MTJ element 10 according to the third embodiment of the present invention;

FIG. 22 is a cross-sectional view of the MTJ element 10 along line A-A′ shown in FIG. 21;

FIG. 23 is a graph illustrating the relationship between the etching rate and the incident angle of the ion beam;

FIG. 24 is a cross-sectional view illustrating a manufacturing step of the MRAM according to the third embodiment;

FIG. 25 is a cross-sectional view illustrating a manufacturing step of the MRAM subsequent to FIG. 24;

FIG. 26 is a cross-sectional view illustrating a manufacturing step of the MRAM subsequent to FIG. 25;

FIG. 27 is a cross-sectional view illustrating a manufacturing step of the MRAM subsequent to FIG. 26;

FIG. 28 is a cross-sectional view illustrating a manufacturing step of the MRAM subsequent to FIG. 27;

FIG. 29 is a cross-sectional view illustrating a manufacturing step of the MRAM subsequent to FIG. 28;

FIG. 30 is a cross-sectional view illustrating a manufacturing step of another configuration example of the MRAM; and

FIG. 31 is a cross-sectional view illustrating a manufacturing step of the MRAM subsequent to FIG. 30.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

### First Embodiment

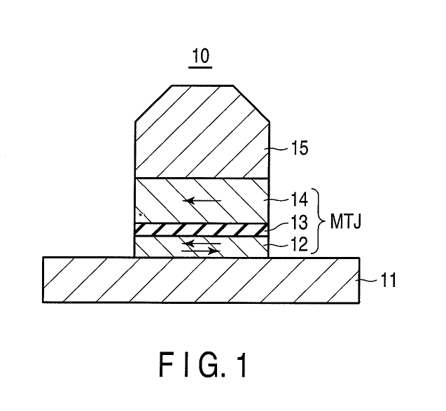

FIG. 1 is a cross-sectional view illustrating a configuration of an MTJ element (magnetoresistive element) 10 according to the first embodiment of the present invention. The MTJ element 10 is a storage element which stores data according to relative magnetization directions of two magnetic layers included therein. The arrows in FIG. 1 denote magnetization directions.

The MTJ element 10 has a stacked structure in which a conductive underlying layer 11, a recording layer (also referred to as free layer) 12, a nonmagnetic layer (tunnel barrier layer) 13, a fixed layer (also referred to as reference layer) 14, and an upper electrode 15 (hard mask layer) are sequentially stacked. In the descriptions that follow, the part including the recording layer 12, the tunnel barrier layer 13 and the fixed layer 14 will be simply referred to as an MTJ. The recording layer 12 and the fixed layer 14 may be stacked in reverse order.

The underlying layer 11 functions as a lower electrode and, as will be described later, as a stopper layer in processing the MTJ, as well as the function as a foundation for controlling crystallization of the magnetic layer arranged thereon. The upper electrode 15 also functions as a hard mask layer in processing the MTJ.

The recording layer 12 has a variable (invertible) direction of magnetization (or spin). The fixed layer 14 has an invariable (fixed) direction of magnetization. The fixed layer 14 having an invariable direction of magnetization means that the magnetization direction of the fixed layer 14 does not vary when a magnetization switching current, which is used to invert the magnetization direction of the recording layer 12, flows through the fixed layer 14. Accordingly, by using a magnetic layer having a large switching current as the fixed layer 14, and using a magnetic layer having a switching current smaller than that of the fixed layer 14 as the recording layer 12 in the MTJ element 10, it is possible to fabricate an MTJ element 10 including a recording layer 12 with a variable magnetization direction and a fixed layer 14 with an invariable magnetization direction. When magnetization inversion is caused by spin-polarized electrons, the switching current is proportional to a damping constant, an anisotropic magnetic field and the volume. By adjusting them properly, a difference in switching current can be provided between the recording layer 12 and the fixed layer 14. Further, magnetization direction of the fixed layer 14 can be fixed by providing an antiferromagnetic layer (not shown) on the fixed layer 14.

The easy magnetization direction of the recording layer 12 and the fixed layer 14 may be perpendicular to the film surface (or the stacked surface) (hereinafter referred to as perpendicular magnetization), or parallel to the film surface (hereinafter referred to as in-plane magnetization). A magnetic layer of the perpendicular magnetization has a magnetic anisotropy perpendicular to the film surface, and a magnetic layer of the in-plane magnetization has a magnetic anisotropy in an in-plane direction. Unlike the in-plane magnetization, the perpendicular magnetization does not require control of the shape of elements in determining the magnetization direction and is advantageously suitable for miniaturization.

Each of the recording layer 12 and the fixed layer 14 is not limited to a single layer as illustrated, and may have a stacked structure including a plurality of magnetic layers. Each of the recording layer 12 and the fixed layer 14 may include the following three layers: a first magnetic layer; a nonmagnetic layer; and a second magnetic layer, and have an antiferromagnetic coupling structure in which magnetic coupling (exchange coupling) is made such that the magnetization directions of the first and second magnetic layers become antiparallel, or a ferromagnetic coupling structure in which magnetic coupling (exchange coupling) is made such that the magnetization direction of the first and second magnetic layers become parallel.

The MTJ element 10 is not particularly limited in terms of shape, and may be in the form of a circle, an oval, a square, a rectangle, or the like. The MTJ element 10 may be in the shape of a square or a rectangle having rounded or beveled corners.

Next, materials for the MTJ element 10 will be described. Preferably, the recording layer 12 and the fixed layer 14 should be formed of high-coercivity magnetic materials, which more specifically should have a magnetic anisotropy energy density higher than 1×10⁶ erg/cc. Example magnetic materials for the recording layer 12 and the fixed layer 14 include an alloy including at least one element from iron (Fe), cobalt (Co) and nickel (Ni), and at least one element from chromium (Cr) platinum (Pt), and palladium (Pd). In order to adjust saturation magnetization, control magnetocrystalline anisotropy energy, and adjust the crystal grain size and crystal grain bonding, impurities such as boron (B), carbon (C), and silicon (Si) may be added to the above-mentioned magnetic materials. The tunnel barrier layer 13 is made of an insulating material, such as magnesium oxide (MgO) and aluminum oxide (Al₂O₃). An example metal for the hard mask layer 15 is tantalum (Ta).

In order to process the MTJ in a desired plane shape, the MTJ film is spatter-etched using the hard mask layer 15 as a mask. In this sputter-etching process, redeposition, which is adhesion of reaction products resulted from etching to the circumferential surface of the MTJ, occurs. The deposit on the circumferential surface of the MTJ due to redeposition causes a short in the recording layer 12 and the fixed layer 14.

According to the present embodiment, in order to remove the deposit on the circumferential surface of the MTJ, when the MTJ film is sputter-etched, excessive etching is performed after the sputter-etching has reached the underlying layer 11, which is called overetching. The overetching is performed until the deposit on the circumferential surface of the MTJ is removed.

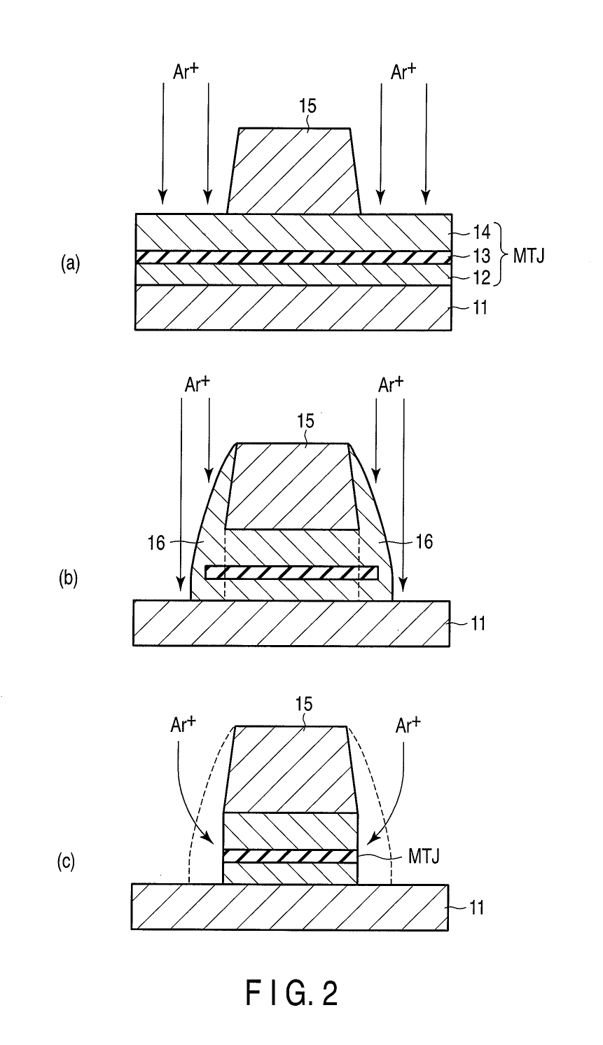

FIG. 2 illustrates overetching performed to remove the deposit on the circumferential surface of the MTJ. First, the underlying layer 11, the MTJ film (the recording layer 12, the tunnel barrier layer 13, the fixed layer 14), and the hard mask layer 15 are sequentially stacked. The hard mask layer 15 is processed into a desired plane shape using lithography and reactive ion etching (RIE), for example.

Next, as shown in FIG. 2(a), plasma of a rare gas such as argon (Ar) is generated, and the MTJ film is sputter-etched using Ar ions (Ar⁺) in the plasma. In sputter-etching, the Ar ions are made incident on an upper surface of the MTJ film approximately perpendicularly, such that the magnetic layer gains a high etching rate. As a result of the sputter-etching of the MTJ film, a deposit 16 resulted from redeposition is formed on the circumferential surface of the MTJ.

FIG. 2(b) illustrates a state in which the underlying layer 11 is exposed by sputter-etching. As shown in FIG. 2 (b), the deposit 16 resulted from redeposition is formed on the circumferential surface of the MTJ.

Then, sputter-etching is further continued to overetch the MTJ. FIG. 2 (c) illustrates a state in which the deposit 16 on the circumferential surface of the MTJ is removed by overetching. This overetching prevents a short in the MTJ.

Since the underlying layer 11 is also etched during the overetching for removal of the deposit 16, the underlying layer 11 becomes thin when the etching rate is not sufficiently low, which causes an increase in resistance of the underlying layer 11. This results in an increase in parasitic resistance of the MTJ element 10, and deterioration of the signal ratio. In view of the circumstances, according to the present embodiment, the conductive material for the underlying layer 11 is selected such that the etching rate of the underlying layer 11 is low under the condition of etching the magnetic layer, i.e., the etching selectivity is high. In other words, the etching rate of the underlying layer 11 is set to be lower than that of the magnetic layers, and the etching selectivity between the underlying layer 11 and the magnetic layers is set to be high. The etching selectivity means the ratio of the etching rate of the target of etching to the etching rate of non-target of etching. Preferably, the etching selectivity, which should be as high as possible, should be greater than or equal to 3 so as not to increase the resistance of the underlying layer 11 during overetching.

Since the circumferential surface of the deposit 16 is declined greatly from the upper surface of the underlying layer 11, the angle (ion incidence angle) at which the Ar ions are made incident on the circumferential surface of the deposit 16 increases. The incident angle means the angle formed by a normal of the etching surface and the vector of the incident ion beam. In order to control redeposition from the underlying layer 11 to the circumferential surface of the MTJ, a conductive material in which the etching rate has great angular dependence upon the case of vertical incidence on the etching surface is required for the underlying layer 11.

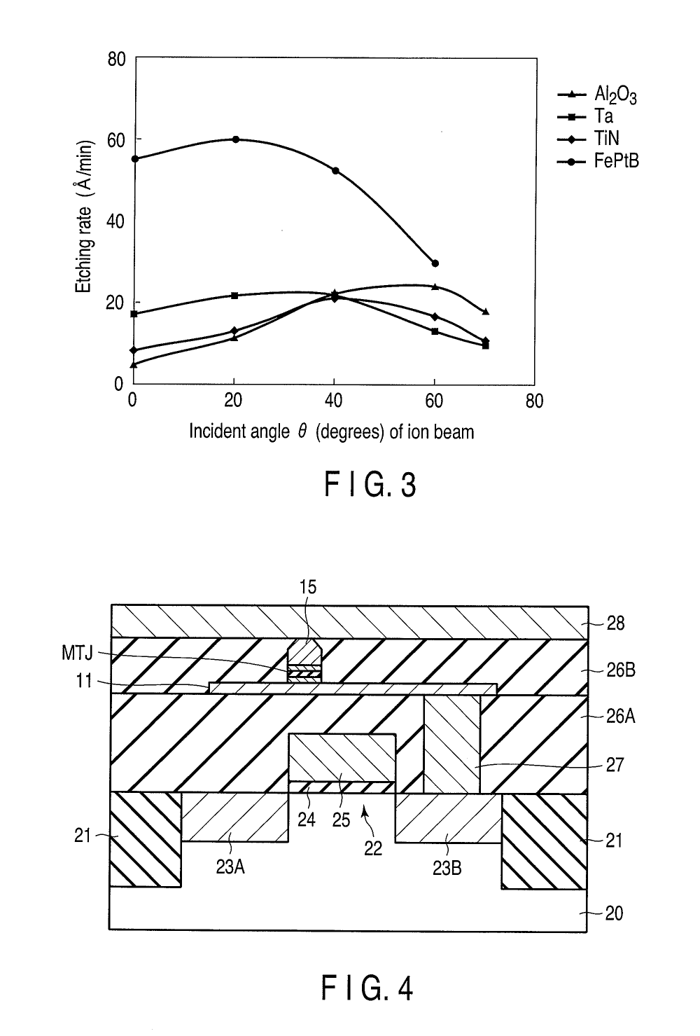

FIG. 3 is a graph illustrating the relationship between the etching rate and the incident angle of the ion beam. The horizontal axis represents the incident angle θ (degrees) of the ion beam, and the vertical axis represents the etching rate (Å/min). Argon (Ar) ions are used as an example of ions for etching, and the accelerating voltage of Ar ions is 200 V, for example. The etching rates of tantalum (Ta) and titanium nitride (TiN) are shown in FIG. 3 as examples of conductive materials used for the underlying layer 11. In addition to them, as an example of a magnetic material used for the recording layer 12 or the fixed layer 14, the etching rate of FePtB is also shown in FIG. 3.

As shown in FIG. 3, the etching selectivity between TiN and FePtB in the case of vertical incidence (where the incident angle θ of the ion beam is zero) on the etching surface is greater than or equal to 3. In TiN, the amount of change in etching rate is large in the range where the incident angle θ of the ion beam is greater than or equal to 0° and less than or equal to 60°, and the etching rate increases with increasing incident angle θ of the ion beam in the range where the incident angle θ of the ion beam is greater than or equal to 0° and less than or equal to 40°. Conductive materials satisfying the above-mentioned conditions include tantalum (Ta), titanium (Ti), titanium nitride (TiN), tantalum nitride (TaN), chromic nitride (CrN), and tantalum silicon nitride (TaSiN). These conductive materials have the common characteristics that the etching selectivity between the conductive material and the magnetic layer (FePtB) is greater than or equal to 3, and that the etching rate is high at a point in the range where the incident angle θ of the ion beam is greater than or equal to 0° and less than or equal to 60°.

The etching rate of the underlying layer 11, to which the amount of a reaction product generated from the underlying layer 11 during overetching is proportional, is the etching rate when the incident angle θ of the ion beam is zero. The etching rate when the deposit from the underlying layer 11 adhered to the circumferential surface of the MTJ is removed by Ar ions is the etching rate when the incident angle of the ion beam is high. Accordingly, by using the underlying layer 11 formed of the above-mentioned conductive material, redeposition from the underlying layer 11 to the circumferential surface of the MTJ can be suppressed, and the deposit from the underlying layer 11 adhered to the circumferential surface of the MTJ can be effectively removed.

Next, a configuration example of an MRAM using the MTJ element 10 illustrated in FIG. 1 will be described. FIG. 4 is a cross-sectional view illustrating a configuration of an MRAM according to the first embodiment.

A substrate 20 of P-type conductivity is a P-type semiconductor substrate, a semiconductor substrate including a P-type well, or a silicon on insulator (SOI) substrate having a p-type semiconductor substrate, for example. For the semiconductor substrate 20, silicon (Si), for example, is used.

The semiconductor substrate 20 includes an element isolation insulation layer 21 in a surface region, and a part of the surface region in which the element isolation insulating layer 21 is not formed becomes an element region (active region) where an element is formed. The element isolation insulation layer 21 is formed by shallow trench isolation (STI), for example. For the STI 21, silicon oxide (SiO₂), for example, is used.

The semiconductor substrate 20 is provided with a select transistor 22 formed of an N-channel metal oxide semiconductor field-effect transistor (MOSFET), for example. The select transistor 22 includes a source region 23A and a drain region 23B formed in the semiconductor substrate 20 to be separated from each other, and a gate electrode 25 formed on a channel region between the source region 23A and the drain region 23B via the gate insulation film 24. Each of the source region 23A and the drain region 23B is formed of an n⁺-type diffusion region formed by introducing high-concentration n⁺-type impurity (such as phosphorus [P] and arsenic [As]) into the semiconductor substrate 20. The gate electrode 25 functions as a word line. The source region 23A is connected to a source line (not shown) via a contact. A current is supplied to the MTJ element 10 via the source line.

An interlayer insulation layer 26A formed of silicon oxide (SiO₂), for example, is provided on the semiconductor substrate 20 to cover the select transistor 22. A conductive plug (contact) 27 electrically connected to the drain region 23B is provided in the interlayer insulation layer 26A. A conductive underlying layer 11, which functions as a lower electrode, is provided on the interlayer insulation layer 26A and the contact 27.

An MTJ in which the recording layer 12, the tunnel barrier layer 13, and the fixed layer 14 are sequentially stacked is provided on the underlying layer 11. An upper electrode 15 is provided on the MTJ. An interlayer insulation layer 26B is provided on the underlying layer 11 and on the periphery of the MTJ and the upper electrode 15. An interconnect layer (bit line) 28 electrically connected to the upper electrode 15 is provided on the interlayer insulation layer 26B and the upper electrode 15. A current is supplied to the MTJ element 10 via the bit line 28. Thus, the MRAM according to the first embodiment is configured.

Next, the operation of writing a binary digit to the MTJ element 10 will be described. When a binary digit is written, the MTJ element 10 is energized bidirectionally in the direction perpendicular to the film surface (or the stacked surface). In this description, a current means a flow of electrons.

First, the operation of switching the magnetization states of the recording layer 12 and the fixed layer 14 from an antiparallel state to a parallel state will be described. In this case, a current flowing from the fixed layer 14 toward the recording layer 12 is supplied to the MTJ element 10. Thereby, electrons having a spin of the direction same as the magnetization direction of the fixed layer 14 are injected into the recording layer 12 having a spin of the opposite direction. When the current density has exceeded Jc_{P→AP}, magnetization inversion occurs in the entire recording layer 12, and the MTJ element 10 switches to a parallel state. The current density Jc_{P→AP} is the current density in the case where the magnetization state of the recording layer 12 and the fixed layer 14 switches from a parallel state (P) to an antiparallel state (AP). In the parallel state, the MTJ element 10 has the least resistance, which is defined as binary 0.

Next, the operation of switching the magnetization states of the recording layer 12 and the fixed layer 14 from a parallel state to an antiparallel state will be described. In this case, a current flowing from the recording layer 12 toward the fixed layer 14 is supplied to the MTJ element 10. Thereby, electrons having a spin of the direction same as the fixed layer 14 is injected into the fixed layer 14 from the recording layer 12, and electrons having a spin of the direction opposite to the direction of the spin of the electrons of the recording layer 12 are injected into the recording layer 12 by reflection of the spin. When the current density has exceeded Jc_{AP→P}, the magnetization inversion occurs in the entire recording layer 12, and the MTJ element 10 switches to an anti-parallel state. The current density Jc_{AP→P} is a current density when the magnetization states of the recording layer 12 and the fixed layer 14 switch from an anti-parallel state (AP) to a parallel state (P). In the anti-parallel state, the MTJ element 10 has the greatest resistance, which is defined as binary 1. Thus, it is possible to record one binary digit in the MTJ element 10.

A binary digit is read by supplying a read current to the MTJ element 10. The value defined by “(R1−R0)/R0” is referred to as the magnetoresistive (MR) ratio, where the resistance in a parallel state is R0 and the resistance in an antiparallel state is R1. The magnetoresistive ratio, which varies according to the material forming the MTJ element 10 and process conditions, can assume percentage values ranging from several tens to several hundreds. By detecting the magnitude of the read current dependent on the magnetoresistive ratio, the binary digit recorded in the MTJ element 10 is read. The read current flowing through the MTJ element 10 during the read operation is set to be sufficiently smaller than that which causes inversion of magnetization in the recording layer 12 as a result of spin injection.

(Method of Manufacturing MRAM)

Next, a method of manufacturing an MRAM according to the present embodiment will be described with reference to the accompanying drawings. First, a select transistor 22 is formed using a publicly-known process in an element region of a semiconductor substrate 20 including the element isolation insulation layer 21.

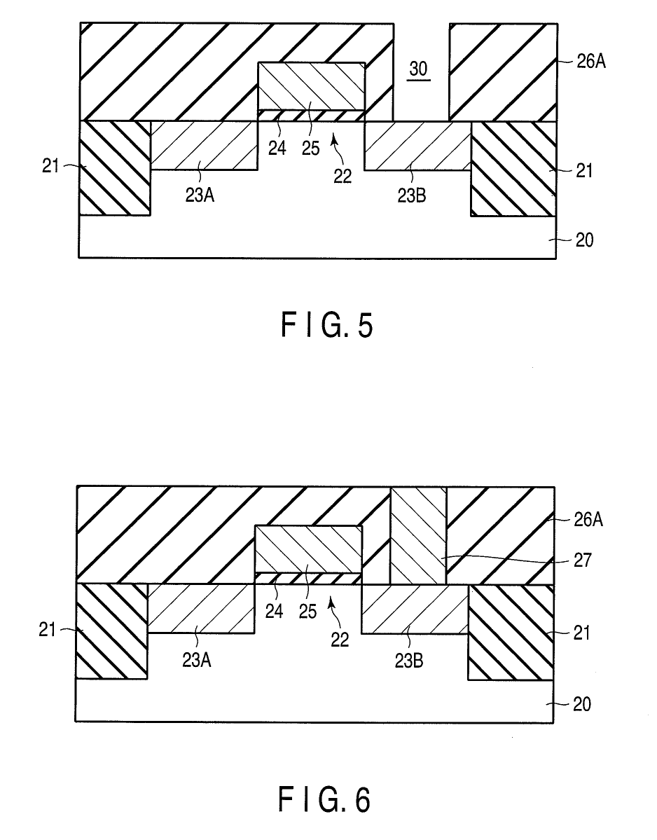

Next, as shown in FIG. 5, an interlayer insulation layer 26A is deposited on the semiconductor substrate 20 to cover the select transistor 22 using chemical vapor deposition (CVD), for example. Then, an opening 30 is formed in the interlayer insulation layer 26A to expose a drain region 23B, using lithography and reactive ion etching (RIE).

After that, as shown in FIG. 6, a conductive material made of tungsten (W), for example, is buried in the opening 30 using sputtering, for example. An upper surface of the interlayer insulation layer 26A and an upper surface of the conductive material are planarized using chemical mechanical polishing (CMP). Thereby, a contact 27 electrically connected to the drain region 23B is formed in the interlayer insulation layer 26A.

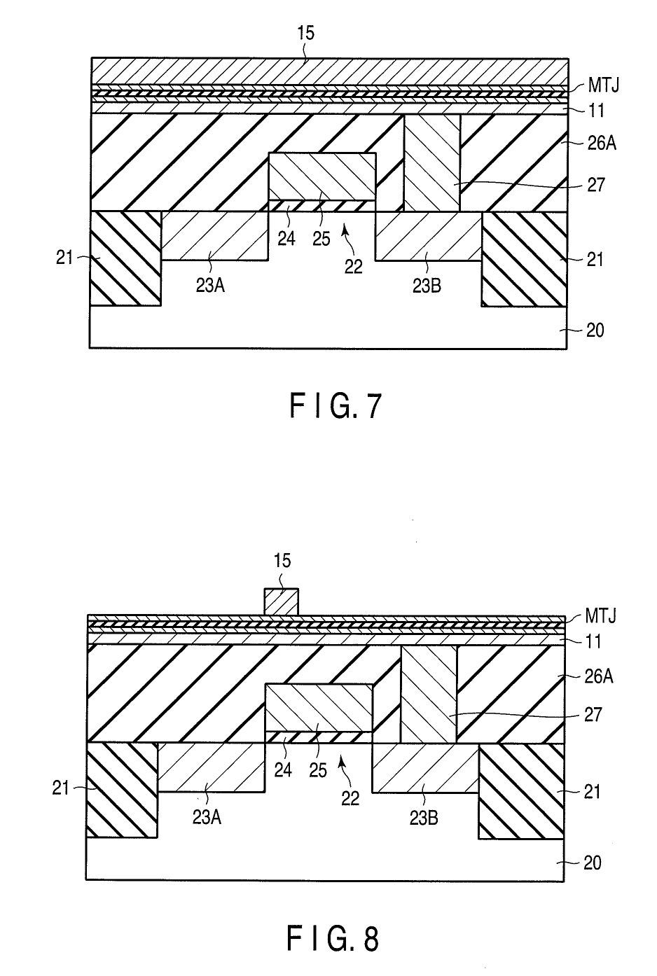

After that, as shown in FIG. 7, the underlying layer (lower electrode) 11, the MTJ (the recording layer 12, the tunnel barrier layer 13, and the fixed layer 14), and the hard mask layer (upper electrode) 15 are sequentially formed on the interlayer insulation layer 26A and the contact 27 using sputtering, for example. The underlying layer 11 is formed using one of the above-mentioned conductive materials. After that, as shown in FIG. 8, the hard mask layer 15 is processed into a shape same as the plane shape of the MTJ element 10 using lithography and RIE.

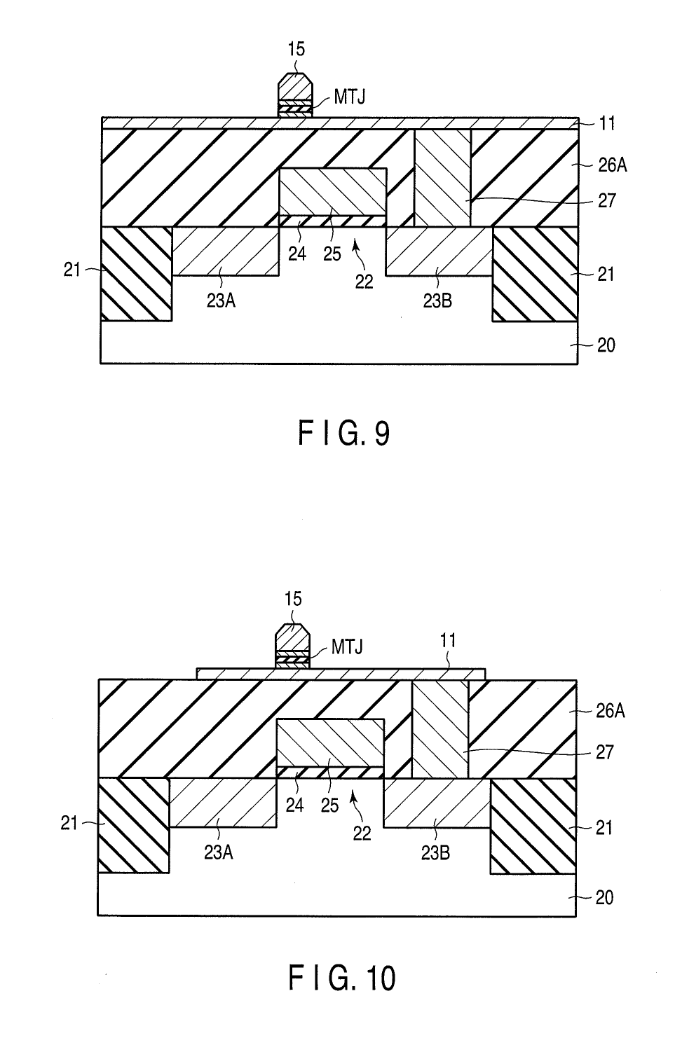

After that, as shown in FIG. 9, the MTJ film is processed by sputter-etching, for example, using the hard mask layer 15 as a mask, and the shape of the hard mask layer 15 is transcribed to the MTJ. After the underlying layer 11 is exposed, overetching is performed to remove the deposit adhered to the circumferential surface of the MTJ. The overetching is performed until the deposit adhered to the circumferential surface of the MTJ is removed. Since the underlying layer 11 is hardly etched in this overetching process, it is possible to suppress decrease in film thickness of the underlying layer 11. Further, redeposition of the underlying layer 11 can also be suppressed. Thereby, it is possible to form an MTJ which has a desired plane shape and does not cause a short path in the recording layer 12 and the fixed layer 14.

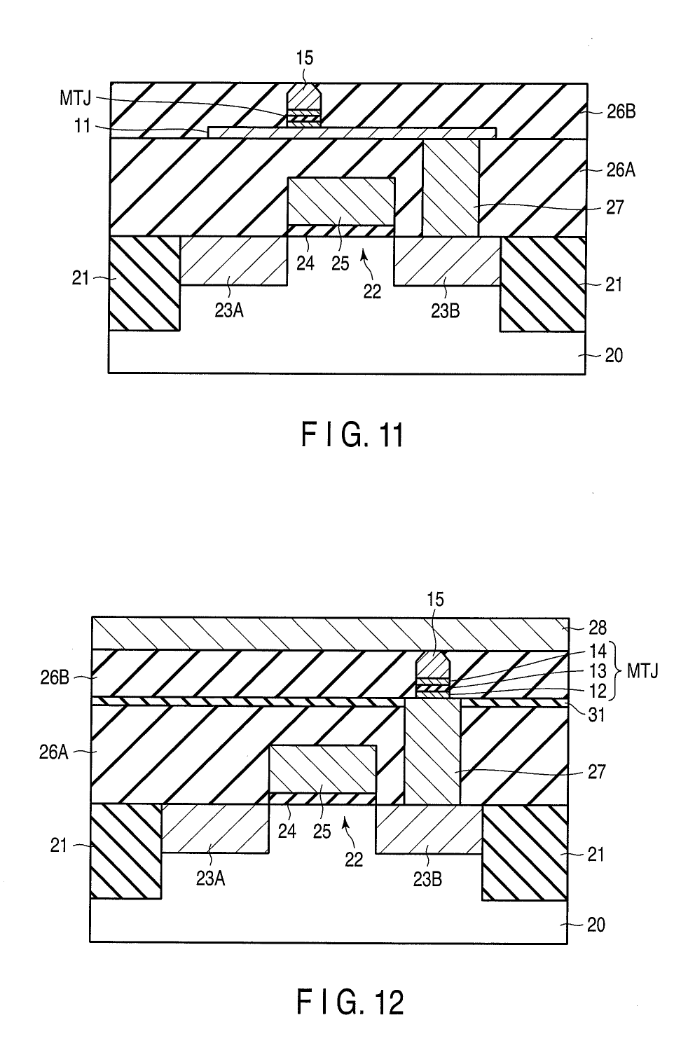

After that, as shown in FIG. 10, the underlying layer 11 is processed into a desired plane shape using lithography and RIE to make the underlying layer 11 function as a lower electrode. After that, as shown in FIG. 11, the interlayer insulation layer 26B is deposited on the interlayer insulation layer 26A using CVD, for example, to cover the underlying layer 11, the MTJ and the hard mask layer 15. After that, the upper surface of the interlayer insulation layer 26B is planarized and the upper surface of the hard mask layer 15 is exposed using CMP.

After that, as shown in FIG. 4, a conductive material made of aluminum (Al), for example, is deposited on the hard mask layer 15 and the interlayer insulation layer 26B using sputtering, for example, and this conductive material is processed using lithography and RIE. Thereby, an interconnect layer (bit line) 28 electrically connected to the hard mask layer 15 is formed. Thus, the MRAM according to the first embodiment is manufactured.

As described above, according to the first embodiment, the MTJ element 10 includes an MTJ in which the recording layer 12, the tunnel barrier layer 13, and the fixed layer 14 are sequentially stacked, and the underlying layer 11 which is provided below the MTJ and functions as a lower electrode. Further, overetching is performed in processing the MTJ. A material having a high etching selectivity with the magnetic layers is used as a conductive material forming the underlying layer 11. In this material, the amount of change in etching rate is large and the etching rate is high at a point in the range where the incident angle θ of the ion beam during etching is greater than or equal to 0° and less than or equal to 60°.

Thus, according to the first embodiment, the deposit 16 adhered to the circumferential surface of the MTJ as a result of sputter-etching of the MTJ can be removed by overetching. Thereby, a short of the MTJ element 10, i.e., formation of a short path between the recording layer 12 and the fixed layer 14 can be prevented. As a result, the probability of occurrence of defects in the MTJ element 10, and in the MRAM in turn, can be reduced.

Further, in processing the MTJ, redeposition from the underlying layer 11 to the circumferential surface of the MTJ can be suppressed, and the deposit from the underlying layer 11 adhered to the circumferential surface of the MTJ can be effectively removed. Thereby, the deposit 16 of the circumferential surface of the MTJ can be effectively removed by overetching.

Moreover, the overetching during the processing of the MTJ suppresses the film thickness of the underlying layer 11 from decreasing. Thereby, the parasitic resistance of the MTJ element 10 can be prevented from increasing, and the signal ratio of the MTJ element 10 can be prevented from deteriorating.

Furthermore, since redeposition from the magnetic layer to the circumferential surface of the MTJ can be prevented without providing a sidewall made of an insulating material, the MTJ element 10 can be miniaturized and variation in shape of the MTJ element 10 can be reduced.

### Second Embodiment

In the second embodiment, instead of the conductive underlying layer 11 used in the first embodiment, an insulating stopper layer 31, made of an insulating material between which and the magnetic layers etching selectivity is high, is newly provided under the MTJ.

FIG. 12 is a cross-sectional view illustrating a configuration of an MRAM according to the second embodiment of the present invention. An insulating stopper layer 31 is provided on the interlayer insulation layer 26A and on the periphery of the conductive plug (contact) 27. The stopper layer 31 is formed on the entire surface of the interlayer insulation layer 26A. The upper surface of the stopper layer 31 is at the same level as the upper surface of the contact 27.

On the contact 27, an MTJ in which a recording layer 12, a tunnel barrier layer 13, and a fixed layer 14 are sequentially stacked is provided. That is, the MRAM of the second embodiment has a structure in which the MTJ is arranged directly on the contact 27, and, unlike the MRAM of the first embodiment, omits the conductive underlying layer 11. An upper electrode 15 is provided on the MTJ. An interlayer insulation layer 26B is provided on the stopper layer 31 and on the periphery of the MTJ and the upper electrode 15. An interconnect layer (bit line) 28 electrically connected to the upper electrode 15 is provided on the interlayer insulation layer 26B and the upper electrode 15. Thus, the MRAM according to the second embodiment is configured.

The etching rate of the stopper layer 31 is set lower than that of the magnetic layers, and the etching selectivity between the stopper layer 31 and the magnetic layers is set high. Preferably, this etching selectivity, which should be as high as possible, should be greater than or equal to 3 in order to reduce the reaction product generated during overetching of the MTJ.

Further, as the insulating material used for the stopper layer 31, a material in which the amount of change in etching rate in the range where the angle incidence θ of the ion beam is greater than or equal to 0° and less than or equal to 60° and the etching rate is high at a point in the range where the incident angle θ of the ion beam is greater than or equal to 0° and less than or equal to 60°. Insulating materials satisfying the above-mentioned conditions include aluminum oxide (Al₂O₃), magnesium oxide (MgO), tantalum pentoxide (Ta₂O₅), titanium oxide (TiO₂), and diamond-like carbon (DLC). DLC is a carbon film including a diamond-like chemical bond (sp³ hybrid orbital). FIG. 3 illustrates aluminum oxide (Al₂O₃) as an example of an insulating material used for the stopper layer 31. In aluminum oxide (Al₂O₃), the amount of change in etching rate is large in the range where the incident angle θ is greater than or equal to 0° and less than or equal to 60°, and the etching rate also increases with increasing incident angle.

In the second embodiment, as in the first embodiment, after the stopper layer 31 is exposed by sputter-etching, the sputter-etching is continued to overetch the MTJ in a process of processing the MTJ. A deposit 16 on the circumferential surface of the MTJ is removed by the overetching.

The etching rate of the stopper layer 31, to which the amount of a reaction product generated from the stopper layer 31 during overetching is proportional, is the etching rate when the incident angle θ of the ion beam is zero. The etching rate when the deposit from the stopper layer 31 adhered to the circumferential surface of the MTJ is removed by Ar ions is the etching rate when the incident angle of the ion beam is high. Accordingly, by using the stopper layer 31 formed of the above-mentioned insulating material, redeposition from the stopper layer 31 to the circumferential surface of the MTJ can be controlled, and the deposit adhered to the circumferential surface of the MTJ from the stopper layer 31 can be effectively removed.

Next, another configuration example of the MRAM according to the second embodiment will be described. When an MTJ is formed directly on the contact 27 as shown in FIG. 12, a part of a top part of the contact 27 is partially exposed between the stopper layer 31 and the MTJ to provide an alignment margin of the MTJ pattern. This raises the possibility that the reaction product of the contact 27 is adhered to the circumferential surface of the MTJ when the MTJ film is sputter-etched. Since the area of the exposed part of the contact 27 is substantially smaller than the area of the stopper layer 31, the amount of adhering reaction product is small. In order to completely prevent the reaction product of the contact 27 from adhering to the circumferential surface of the MTJ, however, an underlying layer 11 is interposed between the contact 27 and the MTJ. A conductive material same as that of the first embodiment is used for the underlying layer 11.

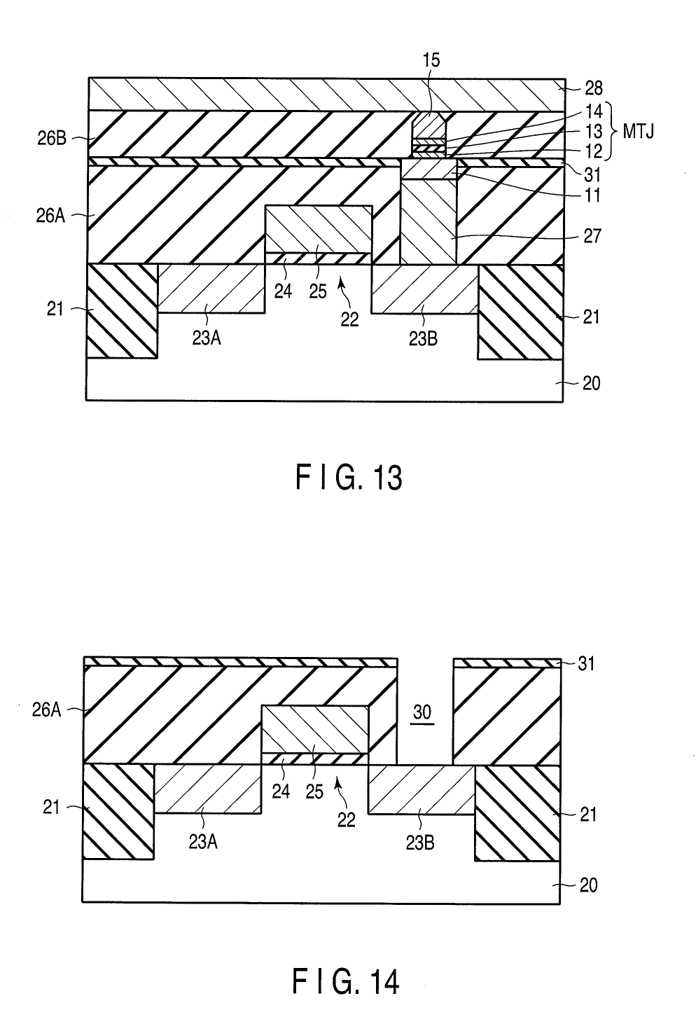

FIG. 13 is a cross-sectional view illustrating another configuration example of the MRAM according to the second embodiment. An underlying layer 11 is provided on the contact 27. An upper surface of the underlying layer 11 is at the same level as the upper surface of the stopper layer 31. A plane shape of the underlying layer 11 is same as that of the contact 27. An MTJ is provided on the underlying layer 11.

In the configuration of FIG. 13, an MTJ can be formed on the low etching rate layers (the underlying layer 11 and the stopper layer 31), and thereby a reaction product during overetching can be reduced. It is therefore possible to reduce a deposit on the circumferential surface of the MTJ, and effectively remove the deposit.

(Method of Manufacturing MRAM)

Next, a method of manufacturing the MRAM according to the second embodiment will be described with reference to the accompanying drawings. First, the select transistor 22 is formed in an element region of the semiconductor substrate 20 including the element isolation insulation layer 21 using a publicly-known process.

Next, as shown in FIG. 14, the interlayer insulation layer 26A is deposited on the semiconductor substrate 20 using CVD, for example, to cover the select transistor 22. Then, the upper surface of the interlayer insulation layer 26A is planarized using CMP. After that, the stopper layer 31 is deposited on the entire surface of the interlayer insulation layer 26A. After that, an opening 30 which exposes the drain region 23B is formed in the interlayer insulation layer 26A and the stopper layer 31 using lithography and RIE.

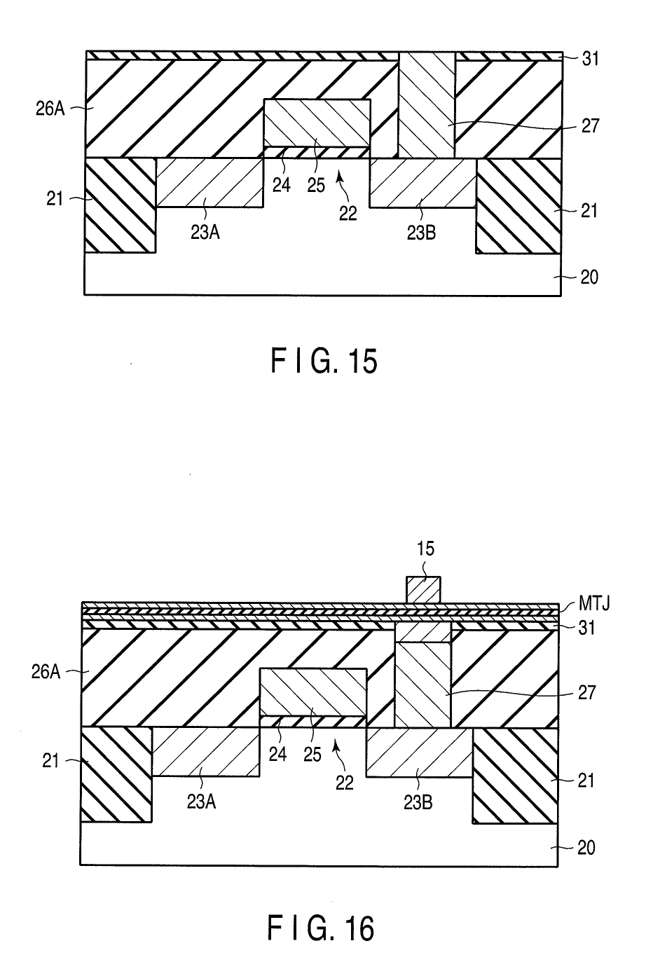

After that, as shown in FIG. 15, a conductive material made of tungsten (W), for example, is buried in the opening 30 using sputtering, for example. The upper surface of the stopper layer 31 and the upper surface of the conductive material are planarized using CMP. Thereby, a contact 27 electrically connected to the drain region 23B is formed in the interlayer insulation layer 26A and the stopper layer 31.

After that, as shown in FIG. 16, the MTJ (the recording layer 12, the tunnel barrier layer 13, and the fixed layer 14), and the hard mask layer (upper electrode) 15 are sequentially formed on the interlayer insulation layer 26A and the contact 27 using sputtering, for example, as shown in FIG. 16. After that, the hard mask layer 15 is processed into a shape same as that of the plane shape of the MTJ element 10 using lithography and RIE. In this case, the hard mask layer 15 is processed to remain above the contact 27.

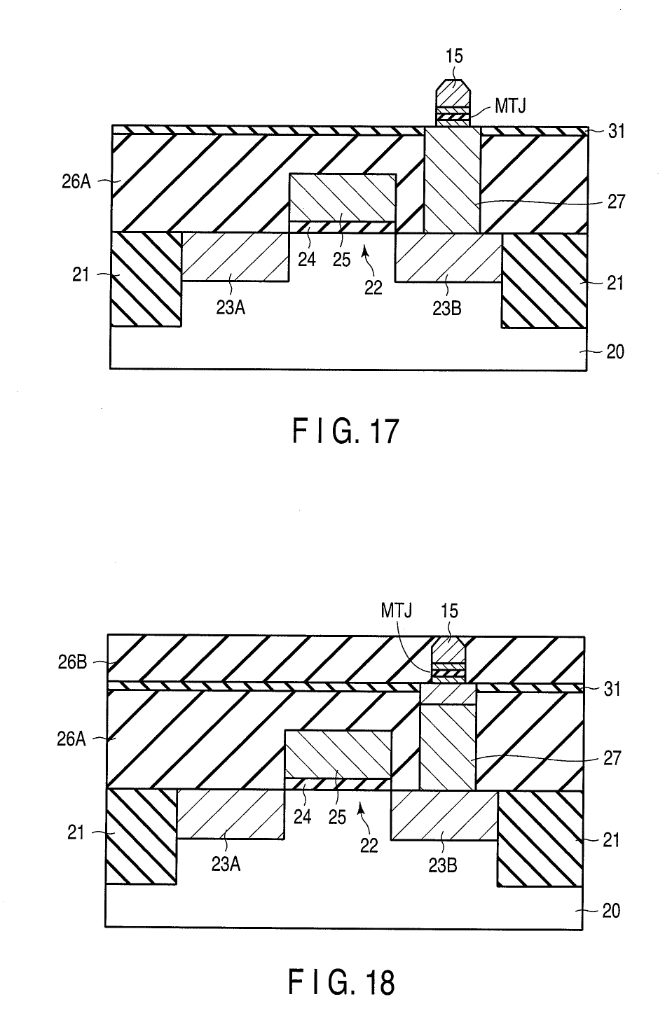

After that, as shown in FIG. 17, the MTJ film is processed by sputter-etching, for example, using the hard mask layer 15 as a mask, and the shape of the hard mask layer 15 is transcribed to the MTJ. In this case, overetching is performed after the stopper layer 31 is exposed, to remove a deposit adhered to the circumferential surface of the MTJ. The overetching is performed until the deposit adhered to the circumferential surface of the MTJ is removed. Since the stopper layer 31 is hardly etched by the overetching process, adhesion of the reaction product of the stopper layer 31 to the circumferential surface of the MTJ can be suppressed. Further, redeposition of the stopper layer 31 can also be suppressed. It is therefore possible to form an MTJ having a desired plane shape and does not have a short path between the recording layer 12 and the fixed layer 14.

After that, as shown in FIG. 18, an interlayer insulation layer 26B is deposited on the stopper layer 31 to cover the MTJ and the hard mask layer 15 using CVD, for example.

After that, the upper surface of the interlayer insulation layer 26B is planarized using CMP, and the upper surface of the hard mask layer 15 is exposed.

After that, as shown in FIG. 12, a conductive material made of aluminum (Al), for example, is deposited on the hard mask layer 15 and the interlayer insulation layer 26B using sputtering, for example, and the conductive material is processed using lithography and RIE. Thereby, an interconnect layer (bit line) 28 electrically connected to the hard mask layer 15 is formed. Thus, an MRAM according to the second embodiment is formed.

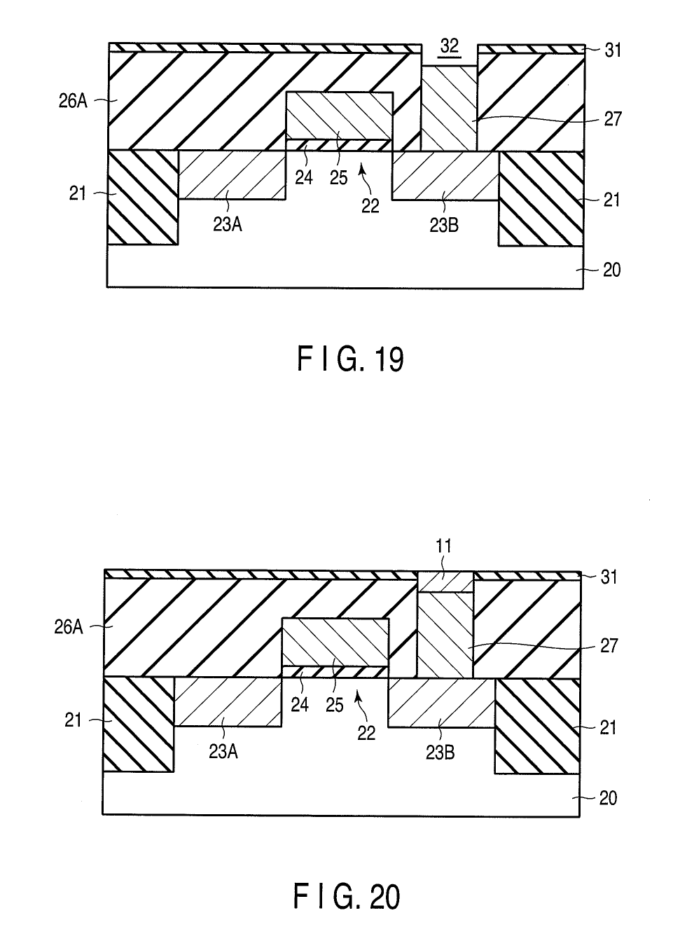

Next, a method of manufacturing the MRAM shown in FIG. 13 will be described. After burying the contact 27 in the interlayer insulation layer 26 and the stopper layer 31, by selectively etching back only the contact 27, as shown in FIG. 19, a recess 32 is formed in the interlayer insulation layer 26 and the stopper layer 31.

After that, as shown in FIG. 20, an underlying layer 11 is deposited in the recess 32 using sputtering, for example, and the conductive material protruded from the recess 32 is removed using CMP. The subsequent process is the same as that of FIGS. 16 to 18.

As described above, in the second embodiment, the stopper layer 31 is provided on the interlayer insulation layer 26A formed on the periphery of the contact 27, and the MTJ is provided directly on the contact 27. Further, overetching is performed during processing of the MTJ. Further, as an insulating material forming the stopper layer 31, a material between which and the magnetic layers etching selectivity is high is used. Further, the amount of change in etching rate of this material is large in the range where the incident angle θ of the ion beam during etching is greater than or equal to 0° and less than or equal to 60°, and the etching rate is high at a point in this range.

Accordingly, according to the second embodiment, as in the first embodiment, the deposit 16 adhered to the circumferential surface of the MTJ as a result of sputter-etching of the MTJ can be removed by overetching of the MTJ. This prevents a short in the MTJ element 10, i.e., formation of a short path between the recording layer 12 and the fixed layer 14. As a result, the incidence of defects in the MTJ element 10, and in the MRAM in turn, can be reduced.

Further, when the MTJ is processed, redeposition from the stopper layer 31 to the circumferential surface of the MTJ can be suppressed, and the deposit from the stopper layer 31 adhered to the circumferential surface of the MTJ can be effectively removed. Thereby, the deposit 16 on the circumferential surface of the MTJ can be effectively removed by overetching.

Moreover, since redeposition from the magnetic layers to the circumferential surface of the MTJ can be prevented without providing a sidewall made of an insulating material, the MTJ element 10 can be miniaturized and variation in shape of the MTJ element 10 can be reduced.

### Third Embodiment

In the third embodiment, a sidewall 40 made of an insulating material having an etching rate lower than that of the magnetic layers is provided on the circumferential surface of the fixed layer 14 in an MTJ in which a recording layer 12, a tunnel barrier layer 13, and a fixed layer 14 are sequentially stacked. The recording layer 12 is processed by substrate-inclined sputter-etching using the sidewall 40 as a mask.

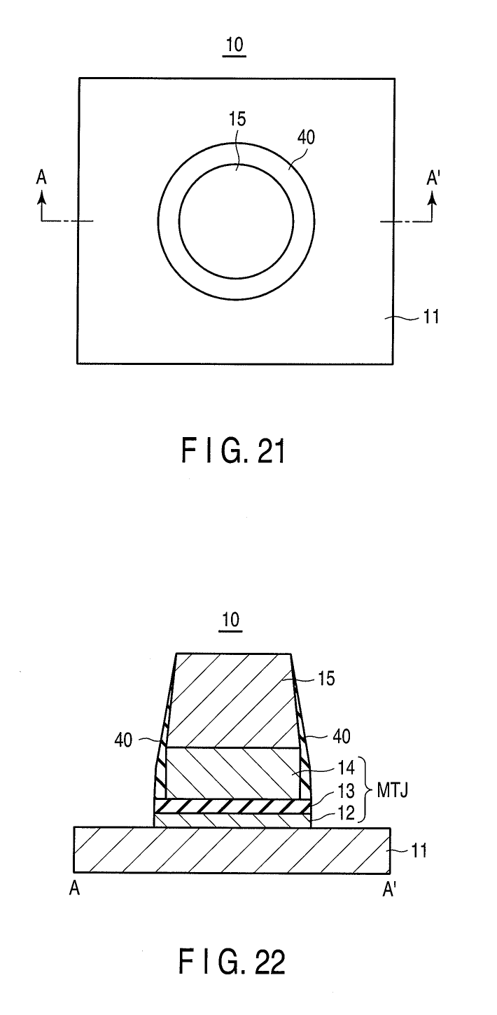

FIG. 21 is a plan view illustrating a configuration of an MTJ element 10 according to the third embodiment of the present invention. FIG. 22 is a cross-sectional view of the MTJ element 10 along line A-A′ shown in FIG. 21. In the third embodiment, a case where the plane shape of the MTJ element 10 is a circle is illustrated as an example.

On the lower electrode 11, an MTJ in which the recording layer 12, the tunnel barrier layer 13, and the fixed layer 14 are sequentially stacked is provided. On the MTJ, a hard mask layer 15, which also functions as an upper electrode, is provided. The lower electrode 11 does not pose limitations on material as in the first embodiment, and a conductive material such as tantalum (Ta) is used.

A sidewall 40 is provided on the fixed layer 14 and the circumferential surface of the hard mask layer 15 such that the sidewall 40 contacts and surrounds the fixed layer 14 and the hard mask layer 15. Accordingly, the area of the upper surface of the recording layer 12 and the tunnel barrier layer 13 is greater than the area of the bottom surface of the fixed layer 14. That is, the fixed layer 14 and the tunnel barrier layer 13 are stepped. In other words, in the cross-sectional shape, the diameter of the bottom surface of the fixed layer 14 is shorter than the diameter of the upper surface of the tunnel barrier layer 13 (or the recording layer 12).

The circumference of the lower part of the sidewall 40 is the same as the circumference of the tunnel barrier layer 13 and the recording layer 12. The sidewall 40 is made of diamond-like carbon (DLC). The DLC film is an amorphous carbon film which contains many carbon atoms having an sp³ hybrid orbital, and has insulating properties.

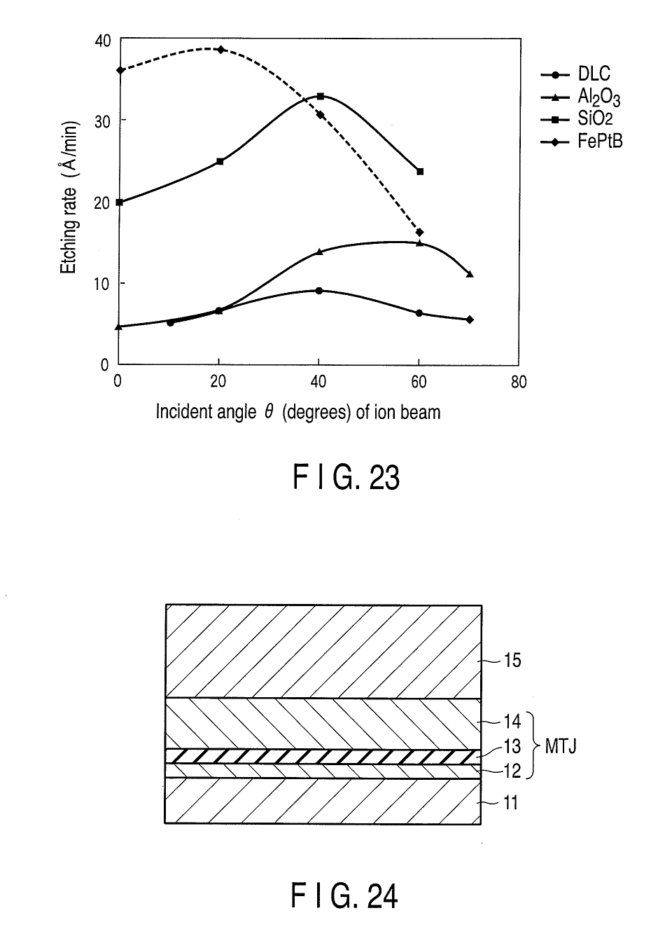

FIG. 23 is a graph illustrating the relationship between the etching rate and the incident angle of the ion beam. The horizontal axis represents the incident angle θ (degrees) of the ion beam, and the vertical axis represents etching rate (Å/min). Argon (Ar) ions, for example, are used as ions for etching, and the accelerating voltage of Ar ions is 200 V, for example. FIG. 23 shows, as well as DLC, aluminum oxide (Al₂O₃) and silicon oxide (SiO₂) as comparative examples, and the etching rate of FePtB as an example of a magnetic material used for the recording layer 12 or the fixed layer 14.

As shown in FIG. 23, DLC has a very low etching rate, which is lower than 10 when the incident angle θ of the ion beam is less than or equal to 70°. Further, in comparison with other materials for insulation films such as Al₂O₃ and SiO₂, DLC has an extremely low etching rate when the incident angle θ of the ion beam is greater than or equal to 20°. Moreover, the etching selectivity between DLC and a magnetic material is greater than or equal to 3 at any incident angle of the ion beam.

Accordingly, by using DLC for the sidewall 40, the amount of etching of the sidewall 40 can be reduced in the process of processing the recording layer 12 by etching even when the incident angle θ of the ion beam is high. Therefore, when the recording layer 12 is processed using the sidewall 40 as a mask, the sidewall 40 can be prevented from being removed.

Although the DLC has been exemplified as an insulating material of the sidewall 40, the same effect as can be obtained by the present embodiment can be obtained by any insulating material having characteristics same as those of DLC, i.e., the etching selectivity between the insulating material and a magnetic material is greater than or equal to 3 at any incident angle, and the etching rate does not greatly increase even when the incident angle of the ion beam increases, in particular.

The configuration of the MRAM according to the third embodiment is the same as the configuration of FIG. 4 except that the configuration of the MTJ element 10 is replaced with that of FIG. 22.

(Manufacturing Method)

Next, the method of manufacturing the MRAM according to the third embodiment will be described with reference to the accompanying drawings. First, although not shown, as in the case of the first embodiment, the select transistor 22 is formed on the semiconductor substrate 20, and the contact 27 electrically connected to the drain region 23B is formed in the interlayer insulation layer 26A on the semiconductor substrate 20.

After that, as shown in FIG. 24, the lower electrode 11, the MTJ (the recording layer 12, the tunnel barrier layer 13, and the fixed layer 14), and the hard mask layer 15 are sequentially stacked by sputtering, for example, on the interlayer insulation layer 26A and the contact 27.

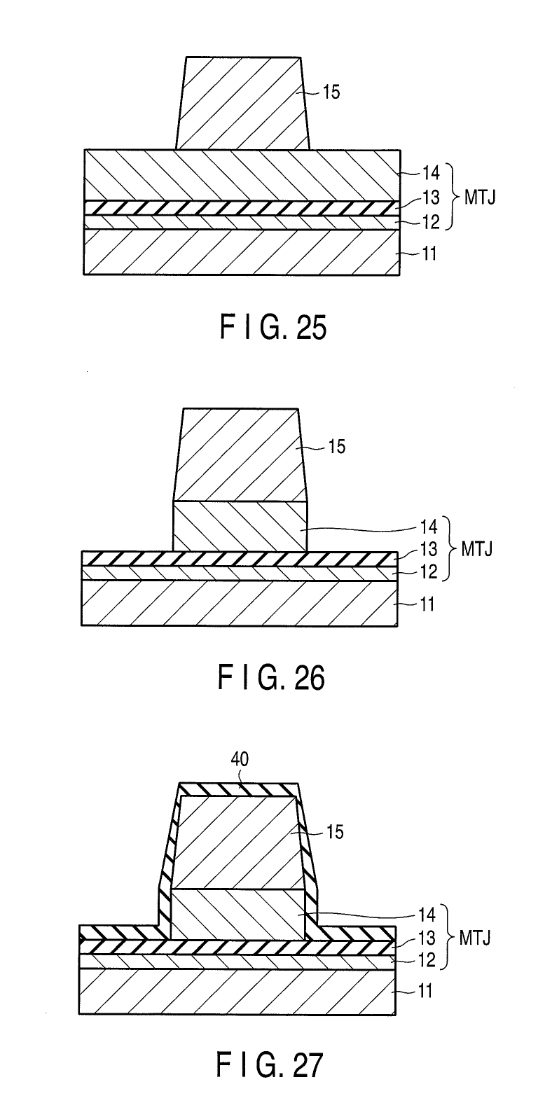

After that, as shown in FIG. 25, the hard mask layer 15 is processed into a shape same as the plan shape of the MTJ element 10 using lithography and RIE.

After that, as shown in FIG. 26, the fixed layer 14 is processed by sputter-etching, for example, using the hard mask layer 15 as a mask, and the shape of the hard mask layer 15 is transcribed to the fixed layer 14. The sputter-etching is finished immediately before it reaches the tunnel barrier layer 13. Thereby, the upper surface of the tunnel barrier layer 13 is exposed.

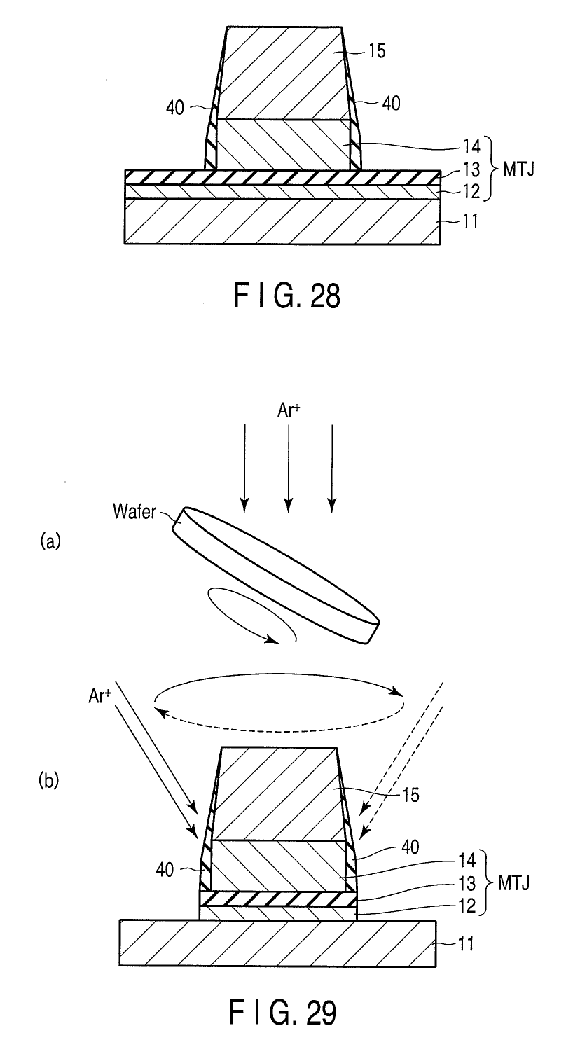

After that, as shown in FIG. 27, a DLC film 40 is deposited on the tunnel barrier layer 13 to cover the hard mask layer 15 and the fixed layer 14 using electron cyclotron resonance CVD (ECR-CVD) or cathode arc deposition, for example. After that, as shown in FIG. 28, the DLC film 40 is etched back, and the sidewall 40 covering the circumferential surface of the hard mask layer 15 and the fixed layer 14 is formed. A Example of the etch back include sputter-etching and RIE using gaseous oxygen, for example.

After that, as shown in FIG. 29, the recording layer 12 and the tunnel barrier layer 13 are processed by substrate-inclined sputter-etching using the sidewall 40 as a mask. FIG. 29 (a) schematically illustrates a substrate-inclined sputter-etching. The wafer shown in FIG. 29 (a) corresponds to the semiconductor substrate 20 including the MTJ element 10 shown in FIG. 28. Ion beams of argon (Ar), for example, travel in the vertical direction. Sputter-etching is performed by inclining the wafer (more specifically, the stage on which the wafer is mounted) 10 to 30°, and simultaneously rotating the wafer. With respect to the wafer surface, the direction of incidence of the ion beam is conically rotated, as shown in FIG. 29 (b). Since the incident angle of the ion beam with respect to the surface of the sidewall 40 decreases, etching of the deposit caused by adhesion of reaction product of the recording layer 12 is promoted and redeposition of the recording layer 12 is suppressed. Therefore, the recording layer 12 can be processed without causing variation in shape. In this case, the sidewall 40 can be prevented from being removed since the etching rate of the sidewall 40 made of DLC is low.

After that, the MRAM undergoes a step of depositing the interlayer insulation layer 26B and a step of forming an interconnect layer (bit line) 28. Thus, an MRAM according to the third embodiment is manufactured.

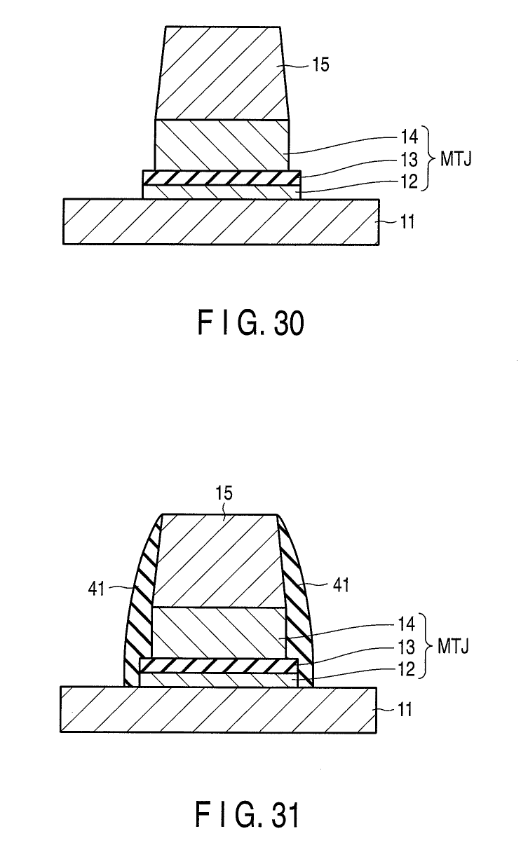

By newly providing the sidewall 40 made of DLC, strain may occur in the magnetic layers forming the MTJ because of stress of the sidewall 40. To address this, the sidewall 40 is selectively removed by asking using oxygen plasma, for example, after the step of processing the recording layer 12 of FIG. 29, as shown in FIG. 30.

When the circumferential surface of the MTJ needs to be protected after that, a new sidewall 41 made of an insulating material having a relatively small stress such as silicon oxide (SiO₂) is formed, as shown in FIG. 31. It is thereby possible to reduce a stress to the MTJ and reduce strain in the magnetic layers forming the MTJ.

As described above, according to the third embodiment, in the MTJ in which the recording layer 12, the tunnel barrier layer 13, and the fixed layer 14 are sequentially stacked, only the fixed layer 14 is processed, and then the sidewall 40 made of DLC having a low etching rate is provided on the circumferential surface of the fixed layer 14. After that, the recording layer 12 is processed by substrate-inclined sputter-etching using the sidewall 40 as a mask.

Accordingly, according to the third embodiment, the incident angle θ of the ion beam can be made low when the ion beam used for sputter-etching is made incident on the sidewall 40. Thereby, redeposition of the recording layer 12 can be suppressed, and deformation in shape of the recording layer 12 caused by the reaction product of the recording layer 12 remaining on the sidewall 40 can be suppressed. As a result, variation in shape of the MTJ element 10 can be reduced.

Further, by using DLC for the sidewall 40, when the recording layer 12 is processed by sputter-etching, the amount of etching of the sidewall 40 can be reduced even when the incident angle θ of the ion beam is large. Therefore, the sidewall 40 can be prevented from being removed at the time of processing of the recording layer 12. This improves the property of the sidewall 40 to protect the magnetic layers, and improves reliability and yield of the MTJ element 10. More specifically, it is possible to prevent deterioration of magnetic characteristics due to ion damage of the fixed layer 14, and a leakage current due to lack of oxygen caused by knocking of oxygen atoms included in the tunnel barrier layer 13.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic memory comprising:
an interlayer insulation layer on a substrate;
a conductive underlying layer on the interlayer insulation layer; and
a magnetoresistive element on the underlying layer and comprising two magnetic layers and a nonmagnetic layer between the magnetic layers,
wherein the underlying layer comprises an etching rate lower than etching rates of the magnetic layers.

2. The memory of claim 1, wherein etching selectivity between the underlying layer and the magnetic layer is greater than or equal to 3.

3. The memory of claim 1, wherein the etching rate of the underlying layer increases as an incident angle of an ion beam increases in a range where the incident angle during etching is greater than or equal to 0° and less than or equal to 40°.

4. The memory of claim 1, wherein the underlying layer is selected from a group consisting of tantalum (Ta), titanium (Ti), titanium nitride (TiN), tantalum nitride (TaN), chromium nitride (CrN) and tantalum silicon nitride (TaSiN).

5. A magnetic memory comprising:
an interlayer insulation layer on a substrate;
a contact in the interlayer insulation layer;
an insulating stopper layer on the interlayer insulation layer surrounding the contact; and
a magnetoresistive element on the contact and comprising two magnetic layers and a non-magnetic layer between the magnetic layers,
wherein the stopper layer comprises an etching rate lower than etching rates of the magnetic layers.

6. The memory of claim 5, wherein etching selectivity between the stopper layer and the magnetic layer is greater than or equal to 3.

7. The memory of claim 5, wherein the etching rate of the stopper layer increases as an incident angle of an ion beam increases in a range where the incident angle during etching is greater than or equal to 0° and less than or equal to 60°.

8. The memory of claim 5, wherein the stopper layer is selected from a group consisting of aluminum oxide (Al₂O₃), magnesium oxide (MgO), tantalum pentoxide (Ta₂O₅), titanium dioxide (TiO₂) and diamond-like carbon (DLC).

9. A magnetoresistive element comprising:
a stacked structure on an underlying layer and comprising a first magnetic layer, a non-magnetic layer, and a second magnetic layer sequentially stacked; and
a sidewall on the nonmagnetic layer in order to cover a circumferential surface of the second magnetic layer, comprising an insulating material, and an etching rate lower than an etching rate of the first magnetic layer.

10. The element of claim 9, wherein etching selectivity between the sidewall and the first magnetic layer is higher than 3.

11. The element of claim 9, wherein the insulating material is diamond-like carbon (DLC).

12. The element of claim 9, wherein an area of a bottom surface of the second magnetic layer is smaller than an area of an upper surface of the nonmagnetic layer.

13. The element of claim 9, wherein a circumference of the sidewall is substantially equal to a circumference of the first magnetic layer.
